(19) United States
(12) Patent Application Publication
(10) Pub. No.: US 2008/0232614 A1
(43) Pub. Date: Sep. 25, 2008

(54) SOUND AMPLIFIER WITH SPEAKER

(75) Inventors: Masanori Kamihara, Musashino-shi (JP); Hironobu Narita, Kodaira-shi (JP); Ryoji Kitanishi, Hachioji-shi (JP)

Correspondence Address: CHRISTENSEN, O'CONNOR, JOHNSON, KINDNESS, PLLC, 1420 FIFTH AVENUE, SUITE 2800, SEATTLE, WA, 98101-2347, US

(73) Assignee: TEAC CORPORATION, Tokyo (JP)

(21) Appl. No.: 12/050,098

(22) Filed: Mar. 17, 2008

(30) Foreign Application Priority Data
Mar. 20, 2007 (JP) 2007-073514

(51) Int. Cl. H03F 21/00

(52) U.S. Cl. 381/120

(57) ABSTRACT

An instrument amplifier includes an amplifier circuit for amplifying a sound signal input from an electric guitar. A main speaker emits sound according to the sound signal being amplified. A CD player plays back an audio signal from an audio CD. Side speakers for playback emits audio sound according to the audio signal being played back. A speaker box contains the main speaker and the side speakers in one space. In one embodiment, the speaker box includes a rear panel for closing a space behind the main speaker and the side speakers. Furthermore, an output mode key is settable in a first mode by external operation, the first mode being for controlling the playback speaker to emit sound according to the sound signal. The side speakers are disposed beside one another, for stereo sound emission of the audio sound.

### BACKGROUND OF THE INVENTION

1. Field of the Invention

The present invention relates to a sound amplifier with a speaker. More particularly, the present invention relates to a sound amplifier with a speaker, in which sounds from two or more sound signal sources can be emitted with a high sound quality even with a simple structure.

2. Description Related to the Prior Art

A guitar amplifier as instrument amplifier is for use with an electric guitar, and is known as an apparatus including an amplifier circuit for amplifying a sound signal and a speaker for emitting sound of the amplified sound signal. When the guitar is connected to the guitar amplifier with a connection cable, the sound signal from the guitar is sent to the guitar amplifier and amplified.

An instrumentalist playing the guitar frequently uses reproduced music to which he or she plays for the purpose of training. To this end, a CD player or other player is prepared and used separately. However, the separate use of the CD player requires much work for handling in addition to the guitar amplifier. JP-A 7-239683 suggests a composite guitar amplifier which includes a component of a player for reproducing music.

U.S. Pat. No. 5,543,579 (corresponding to JP-U 3007106) discloses an effects apparatus including first and second speakers, the first speaker emitting sound of a component of high frequency of effect sound created by effect processing of a direct sound. The second speaker emits sound obtained by addition of the direct sound and a component of low frequency of the effect sound. Two units of the first speaker are disposed on the right and left sides of the second speaker.

However, in U.S. Pat. No. 5,543,579 (corresponding to JP-U 3007106), keeping sound quality of sound in relation to the combined speakers is not suggested, as there is no suggestion of a shape of the speaker box. Should the plural speakers different in property for the frequency of emitted sound be contained in a single speaker box, sound quality of emitted sound may be poor in relation to any one of the speakers. No high sound quality of sound emission can be obtained as a single sound amplifier.

### SUMMARY OF THE INVENTION

In view of the foregoing problems, an object of the present invention is to provide a sound amplifier with a speaker, in which sounds from two or more sound signal sources can be emitted with a high sound quality even with a simple structure.

In order to achieve the above and other objects and advantages of this invention, a sound amplifier includes an amplifier circuit for amplifying a sound signal input from an external sound signal source. At least one main speaker emits sound according to the sound signal being amplified. A player plays back an audio signal recorded in a recording medium. At least one playback speaker emits audio sound according to the audio signal being played back. A speaker box contains the main speaker and the playback speaker in one space, the speaker box having a front panel in which plural apertures are formed and associated with the main speaker and the playback speaker.

The speaker box includes a rear panel for closing a space behind the main speaker and the playback speaker.

The playback speaker is constituted by a plurality of playback speakers, disposed beside one another, for stereo sound emission of the audio sound.

Furthermore, an effects circuit is connected with the amplifier circuit, for effect processing of the sound signal.

Furthermore, an externally operable output mode selector sets first and second modes selectively, the first mode being for controlling the main speaker to emit sound according to the sound signal, the second mode being for controlling at least the playback speaker to emit sound according to the sound signal.

The output mode selector designates at least one of the main speaker and the playback speaker, and drives the at least one designated speaker to emit sound of the sound signal after effect processing by the effects circuit.

Furthermore, a bass enhancing opening is formed in a front panel of the speaker box, for enhancing an output level of a low frequency component emitted by the playback speaker.

Furthermore, a cylindrical bass enhancing port is formed in the speaker box to extend from the bass enhancing opening, for enhancing an output level of a low frequency component emitted by the playback speaker.

The sound signal source is an electric instrument, and the audio source is an optical information recording medium loadable in the player.

Furthermore, a playback amplifier circuit amplifies the audio signal to send the audio signal to the playback speaker.

Furthermore, a player case is secured to an upper face of the speaker box, for containing the player.

Furthermore, a power source unit is contained in the speaker box, for supplying power for use in sound emission.

Furthermore, a grip portion is secured to at least one side face of the speaker box.

The sound signal is generated by manual operation with the sound signal source, and the audio sound is adapted to guiding the manual operation with the sound signal source.

Consequently, it is possible in the sound amplifier to emit sounds from two or more sound signal sources with a high sound quality even with a simple structure.

### BRIEF DESCRIPTION OF THE DRAWINGS

The above objects and advantages of the present invention will become more apparent from the following detailed description when read in connection with the accompanying drawings, in which:

FIG. 1 is a perspective view illustrating a guitar amplifier of the invention;

FIG. 2 is an exploded perspective view illustrating a speaker box of the guitar amplifier;

FIG. 3 is a cross section illustrating the guitar amplifier at a main speaker;

FIG. 4 is a cross section illustrating the guitar amplifier at a right side speaker;

FIG. 5 is a top plan illustrating the guitar amplifier;

FIG. 6 is a block diagram illustrating circuit elements in the guitar amplifier;

FIG. 7 is a graph illustrating characteristic curves of a sound signal of the main speaker; and

FIG. 8 is a graph illustrating characteristic curves of an audio sound signal of the side speakers.

### DETAILED DESCRIPTION OF THE PREFERRED EMBODIMENT(S) OF THE PRESENT INVENTION

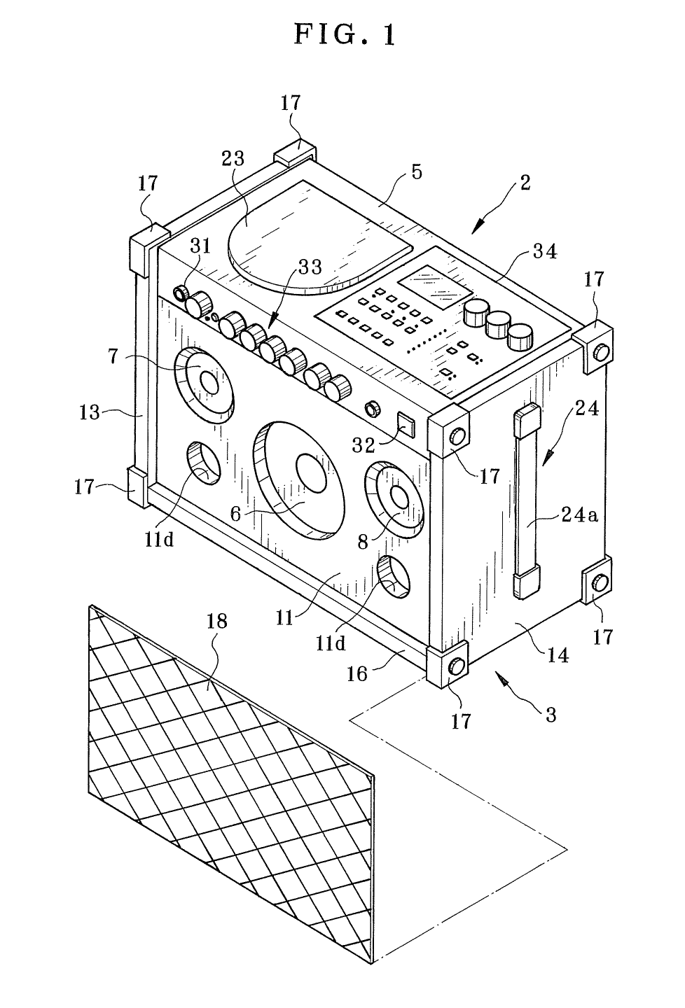

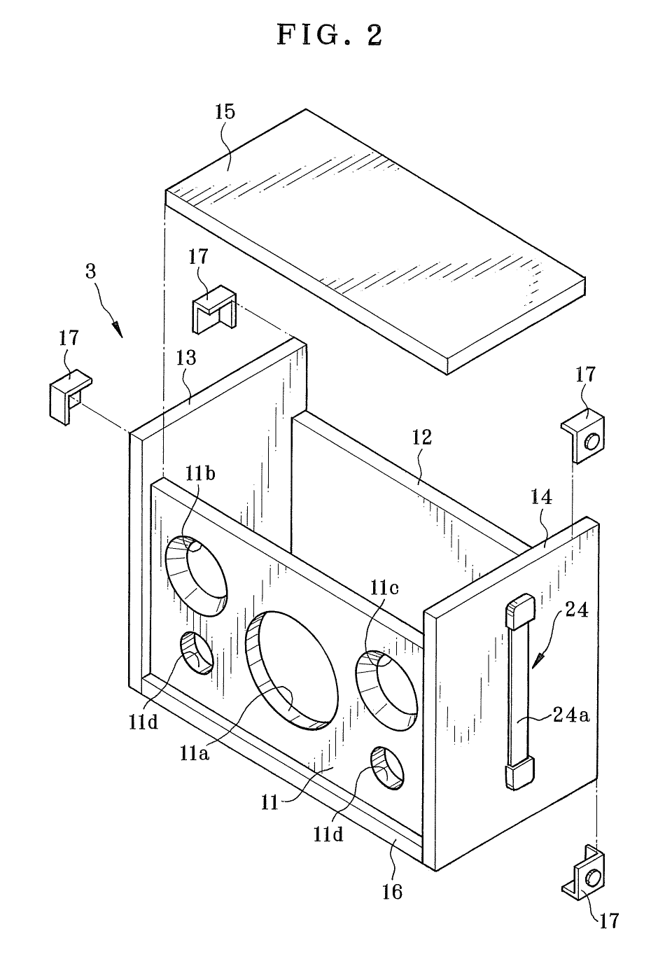

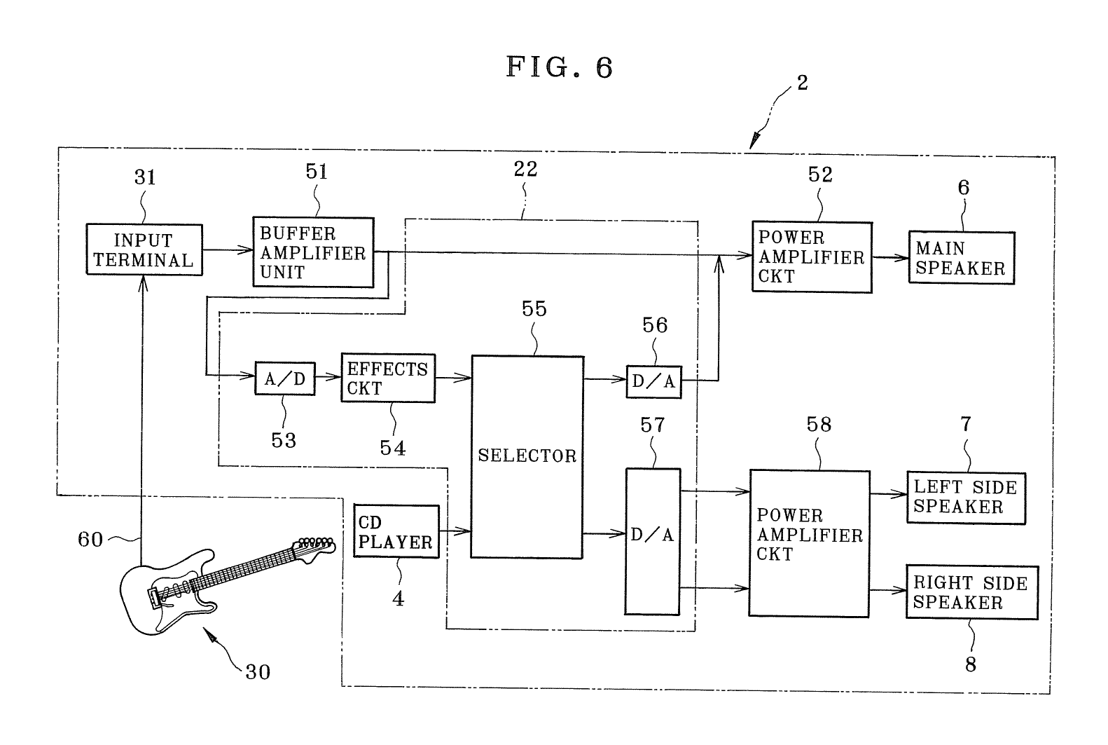

In FIGS. 1 and 2, a guitar amplifier 2 as sound amplifier of the invention includes a speaker box 3, a CD player 4 (See FIG. 6), a player case 5, a main speaker or center speaker 6, a left side speaker 7 as playback speaker, and a right side speaker 8 as playback speaker.

In FIGS. 1-4, the speaker box 3 includes a front panel 11, a rear panel 12, a left side panel 13, a right side panel 14, an upper panel 15 and a lower panel 16. The main speaker 6 and the side speakers 7 and 8 are contained in a single space surrounded by the panels 11-16. The front panel 11 and the rear panel 12 are positioned on an upper surface of the lower panel 16. The left side panel 13 and the right side panel 14 are positioned on end faces of the lower panel 16. The upper panel 15 is positioned between the side panels 13 and 14. Each of the panels 11-16 is constituted by medium density fiberboard (MDF). An outer sheet of a decorative form is attached to each of those for improved appearance. Screws (not shown) are used for fastening the panels 11-15. Reinforcing plates (not shown) are attached to inner surfaces of the speaker box 3 for reinforcement as cabinet.

The main speaker 6 emits sound of a musical instrument after the amplification. Screws (not shown) are used to secure the main speaker 6 to the inside of the front panel 11. The side speakers 7 and 8 are secured to the inner surface of the front panel 11 with screws (not shown), and emit audio sound of music according to an audio signal played back by the CD player 4 as a stereo output. The left side speaker 7 is positioned on the left of the main speaker 6. The right side speaker 8 is positioned on the right of the main speaker 6. A space behind the main and side speakers 6-8 is closed by the rear panel 12, which constitutes a bass reflex structure in the field of the loudspeaker.

Protectors 17 are disposed on four corners of each of the side panels 13 and 14 for protecting the guitar amplifier 2. If the guitar amplifier 2 falls incidentally, the panels 11-14 are prevented from damage because the protectors 17 are struck on a floor surface where the guitar amplifier 2 is installed. Note the only four of the eight of the protectors 17 are depicted in FIG. 2 for simplicity.

The front panel 11 includes a center aperture 11a, a left aperture 11b, and a right aperture 11c. The center aperture 11a passes sound from the main speaker 6 in the forward direction as viewed from the speaker box 3. The left aperture 11b passes sound from the left side speaker 7 in the forward direction. The right aperture 11c passes sound from the right side speaker 8 in the forward direction. A bass enhancing opening 11d in a circular shape is formed in the front panel 11 and under each of the apertures 11b and 11c for preventing damping or a poor output in a low frequency range of emitted sound. A shape of the bass enhancing opening 11d can be any suitable form other than the circular form. It is possible additionally to form a bass enhancing opening in one or more of the rear panel 12, the side panels 13 and 14 and the lower panel 16. A speaker net 18 is secured to the front panel 11 in a removable manner.

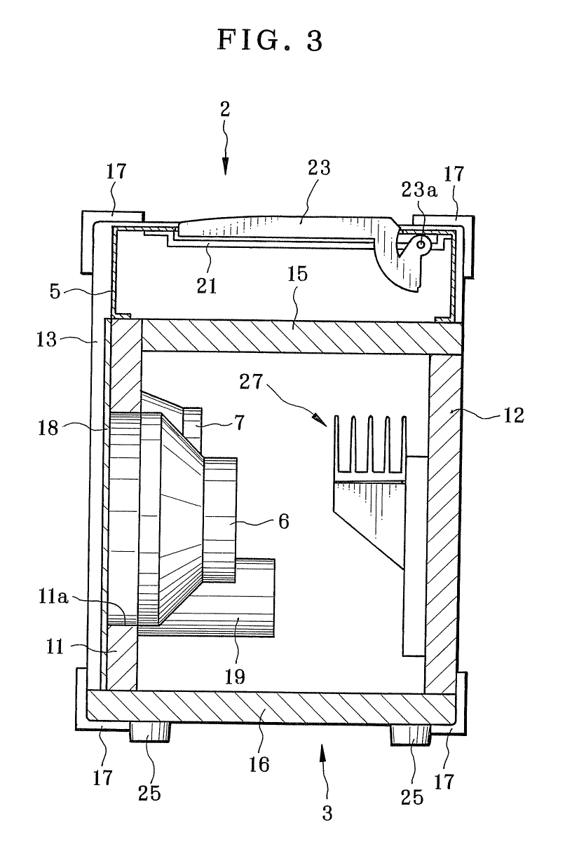

No large openings like the apertures 11a-11d are formed in any of the panels 12-16 having screw holes and the like of a small size. A power source unit 27 is contained in the speaker box 3 of FIG. 3, and is secured to an inner surface of the rear panel 12.

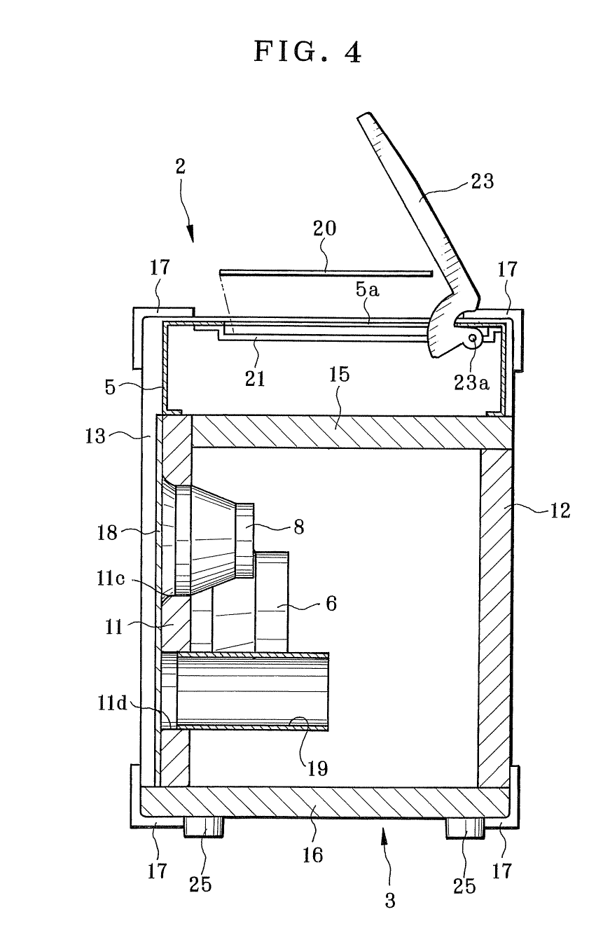

In FIGS. 3 and 4, bass enhancing ports 19 in a cylindrical shape are formed with the front panel 11 for enhancing an output level of a low frequency component of sound from the side speakers 7 and 8. Each of the bass enhancing ports 19 is shaped to extend to the bass enhancing opening 11d. A length of the bass enhancing ports 19 can be determined with modifications in compliance with various factors, such as an internal volume of the speaker box 3, an output power of the side speakers 7 and 8 (in watt), and the like. A shape of the bass enhancing ports 19 can be any suitable form other than the cylindrical form, for example a form of a quadrilateral prism and the like.

The player case 5 is disposed on the upper surface of the upper panel 15 between the side panels 13 and 14 for containing the CD player 4. Any of various known structures may be used for the CD player 4. Elements in the CD player 4 includes a disk tray 21, an optical pickup, a spindle motor, and a frame. The disk tray 21 supports an audio CD 20 or optical information recording medium as audio source. The optical pickup accesses a recording surface of the CD 20 for reading. The spindle motor rotates the CD 20. Note that the CD player 4 may be any of a type for reading only and a recording type capable of both recording and playback of an audio signal on the recording surface of CD-R/RW as recording medium.

The player case 5 is formed from metal. A circuit board 22 of FIG. 6 is contained in the player case 5 and has circuit elements to control the amplification and sound emission in the guitar amplifier 2. Various materials can be used for forming the player case 5, for example resin.

A player opening 5a is formed in an upper wall of the player case 5 for the disk tray 21 to appear. A player cover 23 is secured to the player case 5 in a pivotally movable manner between an open position of FIG. 4 to uncover the disk tray 21 through the player opening 5a and a closed position of FIG. 3 to close the player opening 5a. A rotating mechanism (not shown) including gears and a spring is incorporated in the player case 5. The player cover 23 is kept rotatable about a pivot 23a by the rotating mechanism. The spring (not shown) biases the player cover 23 toward the open position. A pressure release type of pressure lock mechanism known in the art is associated with the player case 5, and locks the player cover 23 when the player cover 23 is rotated down to the closed position from the open position, and unlocks the player cover 23 when a front end of the player cover 23 is depressed manually in the closed position.

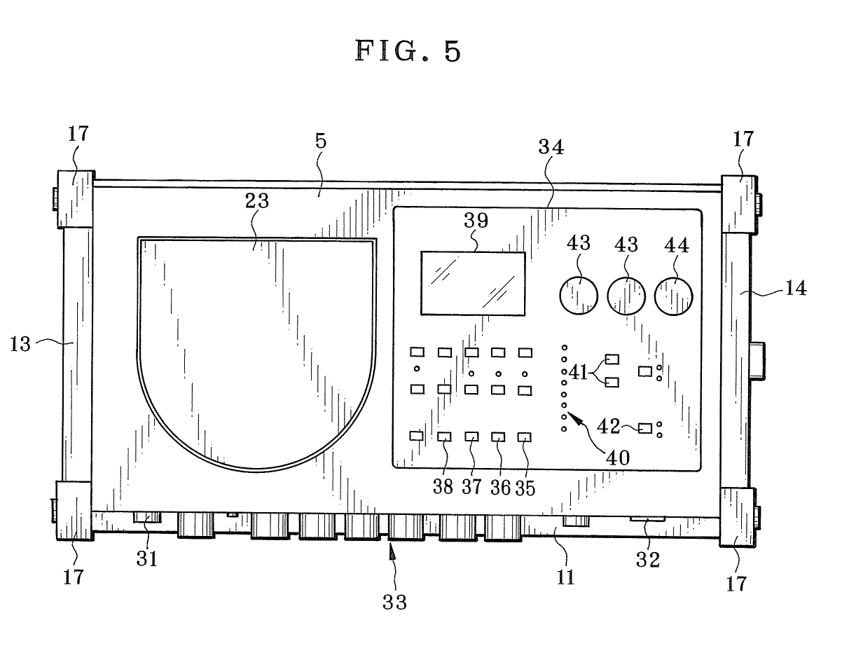

In order to play the CD 20 in the CD player 4, at first the front end of the player cover 23 is depressed in the state of the closed position, to unlock the player cover 23. In response to this, the spring pops up the player cover 23 rotationally to the open position. The CD 20 is placed on the disk tray 21, before the player cover 23 is manually pushed down rotationally and locked in the closed position. Then a play key 35 of FIG. 5 is depressed, to play the CD 20.

In FIGS. 1 and 2, a grip portion 24 is secured to the right side panel 14 by screws (not shown) for manually carrying the guitar amplifier 2. A grip belt 24a of the grip portion 24 is grasped by a user for carrying. Note that a second grip portion may be additionally secured to the left side panel 13.

In FIGS. 3 and 4, supports 25 are secured to lower surfaces of four corners of the lower panel 16 by screws (not shown), and operate for supporting the guitar amplifier 2 in the placement with the upper panel 15 directed upwards. As the supports 25 support the guitar amplifier 2, the lower panel 16 does not contact the floor surface in the installed state.

The power source unit 27 is disposed in the speaker box 3, and has a power source and a heat sink for dissipating heat. Screws (not shown) are used to keep the power source unit 27 fastened on the rear panel 12. Note that the power source unit 27 is not shown in FIG. 4 for the purpose of simplicity.

In FIG. 1, a front face of the player case 5 has an input terminal 31 and a power switch 32. A sound signal from an electric guitar 30 as sound signal source is input to the input terminal 31. The power switch 32 is operable to turn on and off the power source of the guitar amplifier 2. Also, the front of the player case 5 has a gain wheel, a boost switch, an LED indicator, a bass wheel, a middle wheel, a treble wheel, a reverb wheel, a center volume wheel, a side volume wheel, a line-in terminal and a headphone terminal. The gain wheel is operable for adjusting the input gain. The boost switch turns on and off an internal distortion circuit. The LED indicator illuminates for indicating the state of turning on the boost. The bass wheel is operable to adjust an output level of a low frequency range. The middle wheel is operable to adjust an output level of a middle frequency range. The treble wheel is operable to adjust an output level of a high frequency range. The reverb wheel is operable to adjust an output level of a reverb signal. The center volume wheel is operable to adjust the volume of the main speaker or center speaker 6. The side volume wheel is operable to adjust the volume of the side speakers 7 and 8. The line-in terminal is connectable with an external device, such as a synthesizer, guitar preamplifier, MD player and the like. The headphone terminal is connectable with a stereo headphone.

In the embodiments, the above-described switches and wheels on the front of the player case 5 are referred to as an input panel 33. When the power switch 32 and the input panel 33 is operated manually, a control signal is sent to the circuit board 22 of FIG. 6, to control the guitar amplifier 2. Note that the protectors 17 extend to project in a forward direction further than the input terminal 31, the power switch 32 and the input panel 33. Should the guitar amplifier 2 fall accidentally in the forward direction, the input terminal 31, the power switch 32 and the input panel 33 on the player case 5 are prevented from being damaged with the fail safe shape of the protectors 17.

In FIG. 5, a key panel 34 is disposed on the top of the player case 5 and beside the player cover 23, and operable manually to operate the guitar amplifier 2 and the CD player 4. The key panel 34 includes the play key 35, a stop key 36, a forward skip key 37, a reverse skip key 38, and an LCD display panel 39. The play key 35 is operable for playing the CD 20 in the CD player 4. The stop key 36 is operable to stop the playback of the CD 20. The forward skip key 37 is operable to skip the track in the playback in the forward direction. The reverse skip key 38 is operable to skip the track in the playback in the reverse direction. The LCD display panel 39 indicates the status of playing the CD 20 and the setting of the guitar amplifier 2. The key panel 34 also has a loop playback key, a tuner key, an EDIT key and a guitar cancel key. The loop playback key is operable to play the CD 20 in a loop playback. The tuner key is operable to turn on and off the tuner mode. The EDIT key is operable to adjust parameters in a setting. The guitar cancel key is operable to remove sound component emitted by a guitar from the audio sound of the side speakers 7 and 8. If the CD player 4 is a disk recorder capable of recording and playback, the key panel 34 additionally includes a record key for starting the recording operation.

Functions of eight effects of an effects circuit are preset in the guitar amplifier 2, including Flanger, Phaser, Chorus, Tremolo, Auto Wah, Pitch Shifter, Delay and Panning Delay. An instrumentalist selects one of the effects of the effects circuit for the sound input from the electric guitar 30 according to purposes or his or her preference. Note that the kinds and the number of the effects in the guitar amplifier 2 can be modified.

In the key panel 34, an effect selection key 41 is operable to select one of the eight effects in the effects circuit for use. An output mode key 42 as output mode selector is disposed beside the effect selection key 41, and is operable to set one of three modes to emit the effect sound signal from the effects circuit, the three modes including a first mode of using the main speaker or center speaker 6, a second mode of using the side speakers 7 and 8, and a third mode of using the main and side speakers 6-8. Eight LEDs 40 are arranged on the left side of the effect selection key 41. Effect names of the effects are indicated beside the LEDs 40. One of the LEDs 40 is driven to illuminate according to the operation of the effect selection key 41. When the effects are not used, the LEDs 40 are turned off. The selected effect according to the present status is recognizable with the associated effect name.

The key panel 34 includes parameter wheels 43 and a level adjusting wheel 44. The parameter wheels 43 are used for setting a parameter of the selected effect of the effects circuit. The level adjusting wheel 44 is used for setting an effect level, feedback level and the like of the selected effect. The parameter wheels 43 are two wheels which set parameters different from one another.

In the embodiment, the key panel 34 is the group of keys and wheels on the top of the player case 5. When any of the input keys 35-38, the effect selection key 41, the output mode key 42, the parameter wheels 43 and the level adjusting wheel 44 in the key panel 34 is operated, a command signal is generated and sent to the circuit board 22 of FIG. 6, to control the guitar amplifier 2 responsively.

In FIG. 6, a buffer amplifier unit 51 is supplied with a sound signal input to the input terminal 31 by the electric guitar 30. The buffer amplifier unit 51 amplifies the analog sound signal. A power amplifier circuit 52 in the main amplifier circuit is supplied with the sound signal from the buffer amplifier unit 51. The power amplifier circuit 52 drives the main speaker 6 with a dry sound signal, which is the sound signal without internal effect processing. The main speaker 6 emits sound of the dry sound signal, or sound the electric guitar 30 before the internal effect processing. Also, an A/D converter 53 is in connection with the buffer amplifier unit 51.

The A/D converter 53 converts the input analog sound signal into a digital sound signal. An effects circuit 54 which has the functions of the selectable effects is supplied with the digital sound signal. The effects circuit 54 is responsive to the command signal from the effect selection key 41, and processes the input digital sound signal with an effect, in various manners known in the field of effect processing. The effects circuit 54 sends the effect sound signal to a selector 55.

The selector 55 as output mode selector operates in response to a signal generated with the output mode key 42, and selectively sets one of three modes to emit sound of the effect sound signal from the effects circuit 54, the three modes including a first mode of using the main speaker 6, a second mode of using the side speakers 7 and 8, and a third mode of using the main and side speakers 6-8. If the first mode is set, a center D/A converter 56 is supplied with the effect sound signal. If the second mode is set, a side D/A converter 57 is supplied with the effect sound signal.

The CD player 4 is connected with the selector 55. The CD player 4 reproduces audio sound of music by playback of audio data in the CD 20. An audio signal is obtained by the CD player 4 and sent to the selector 55. The audio signal from the CD player 4 is output by the selector 55 to the side D/A converter 57.

The center D/A converter 56 converts the input digital sound signal or effect sound signal into an analog sound signal, which is sent to the power amplifier circuit 52. The side D/A converter 57 converts the input digital sound signal into an analog sound signal, the digital sound signal being the effect sound signal and/or audio signal. A power amplifier circuit 58 as playback amplifier circuit is supplied with the analog sound signal by the side D/A converter 57.

The power amplifier circuit 52 amplifies the dry sound signal from the buffer amplifier unit 51 and the effect sound signal from the center D/A converter 56, and then responsively drives the main speaker 6, which emits sound of the electric guitar 30.

The power amplifier circuit 58 amplifies the effect sound signal and audio signal from the side D/A converter 57, and then drives the side speakers 7 and 8 to emit sound. In relation to the disposition, the buffer amplifier unit 51, the power amplifier circuit 52 and the power amplifier circuit 58 are contained in the speaker box 3 or the player case 5.

To use the guitar amplifier 2, at first an instrumentalist connects a connection cable 60 between an output of the electric guitar 30 as sound signal source and the input terminal 31. Then the input panel 33 and the key panel 34 of the player case 5 are operated to select effects of the effects circuit, the modes of outputs of the effect sound signal, the adjustment of the volume of the main and side speakers 6-8 and the like. When he or she plays the electric guitar 30, sound signal is sent from the electric guitar 30 to the input terminal 31 to emit sounds from the main and side speakers 6-8. Sound of the dry sound signal is emitted by the main speaker 6. Sound of the effect sound signal is emitted by at least any one of the main speaker 6 and the side speakers 7 and 8. When he or she wishes to train oneself on the electric guitar 30, the CD 20 is set on the disk tray 21, and played by operating the input keys 35-38 and the key panel of the player case 5. Audio sound of the audio signal derived by playing the CD 20 in the CD player 4 is emitted by the side speakers 7 and 8 as a stereo output. The instrumentalist can play the electric guitar 30 by carefully listening to the audio sound of the music emitted by the side speakers 7 and 8 for training, check of playing and sound, or other purposes.

Note that the CD player 4 can be a disk recorder which is capable of both recording and playback. A CD-R/RW as recording medium can be set in the disk recorder, to record sound of the guitar played by the instrumentalist upon operating a recording key (not shown) in the key panel 34. To this end, the disk recorder is connected with the A/D converter 53. A sound signal from the electric guitar 30 is input through the input terminal 31 and the buffer amplifier unit 51, and is converted by the A/D converter 53 into a digital sound signal, which is input to the disk recorder and recorded to the recording medium. It is possible to input the effect sound signal from the effects circuit 54 to the disk recorder.

### EXAMPLE

In the guitar amplifier 2, a test signal of −10 dBu was input to the input terminal 31. A microphone was used to pick up a center output signal of sound emitted by the main speaker 6, and a side output signal of sound emitted by the side speakers 7 and 8. The signals were transmitted to a mixer, and were measured by a measuring device (manufactured by Audio Precision Inc.). Experiment was conducted for a sample in which the rear panel 12 was disposed behind the main and side speakers 6-8 in a closed shape according to the invention, and for a comparison in which a rear space of the main and side speakers 6-8 was open. The volume of the main and side speakers 6-8 was set at a middle level which was between the minimum and maximum.

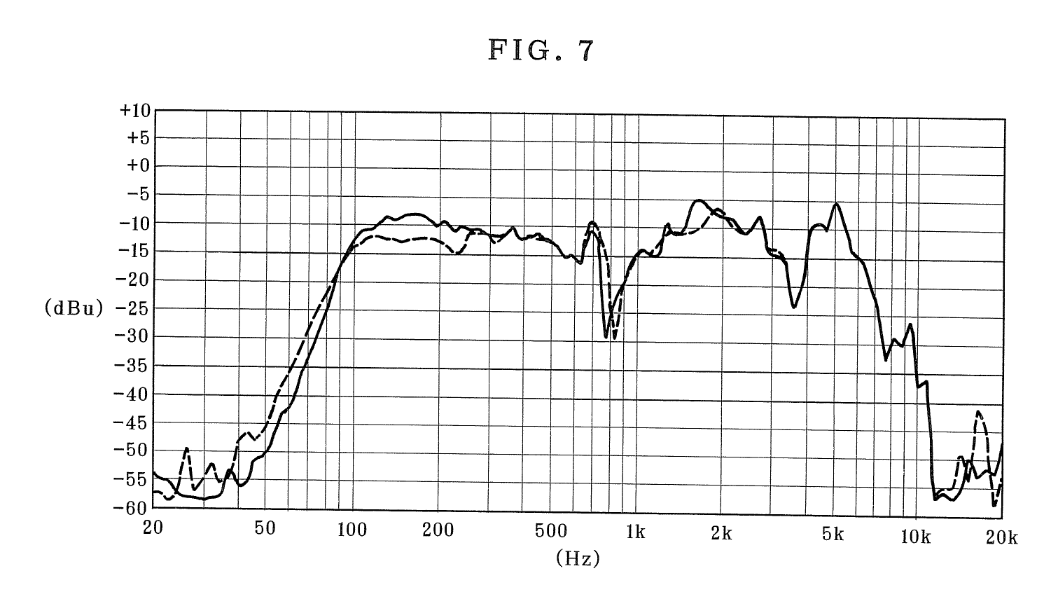

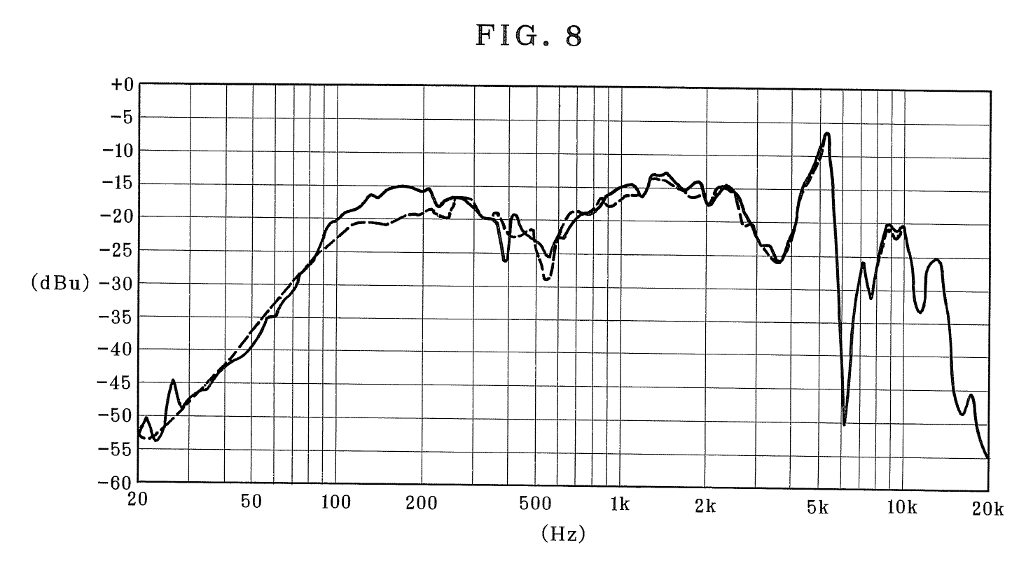

Results of the experiment are illustrated in FIG. 7 as a graph for outputs of the center, and FIG. 8 as a graph for outputs of the sides. In those graphs, the solid line indicates measurement data obtained from the suggested sample with the rear panel 12 to close the rear. The broken line indicates measurement data obtained from the comparative structure with the open space behind the main and side speakers 6-8.

As a result, the output level in the low frequency range of 90-220 Hz was found higher by approximately 5-6 dB in the suggested sample having the rear panel 12 than in the comparison with the open space behind the main and side speakers 6-8. Improvement of the output level was found according to the center output signal from the main speaker 6 and the side output signal from the side speakers 7 and 8.

It is possible to reduce the size of the guitar amplifier 2 and also its cost as advantages over complicated structures of a speaker box in the conventional amplifier, because the main speaker 6 and the side speakers 7 and 8 are contained in the single space in the speaker box 3.

It is possible to enhance an output level of the low frequency range of sound emitted by the main and side speakers 6-8 because the rear panel 12 closes the rear space, in comparison with a known type in which a space behind the main and side speakers 6-8 is open.

Also, the bass enhancing opening 11d in the front panel 11 of the speaker box 3 is effective in preventing a poor output of the low frequency of the sound emitted by the left side speaker 7 and the right side speaker 8. Thus, the instrumentalist can train oneself on the electric guitar 30 readily together with the music or audio sound emitted by the side speakers 7 and 8, because the music from the CD 20 is easy to hear.

As the bass enhancing ports 19 communicate with the bass enhancing openings 11d for enhancing the output level of the low frequency in the outputs of the side speakers 7 and 8, the output level of the low frequency can be sufficiently high in an ensured manner.

It is possible to emit audio sound as a stereo output even in a compact size of the amplifier, because the side speakers 7 and 8 are disposed on the left and right of the main speaker 6.

Sound of the dry sound signal, which is before the internal effect processing, is emitted by the main speaker 6. For sound of the effect sound signal, the three modes of output are selectable, including the first mode of using the main speaker 6, the second mode of using the side speakers 7 and 8, and the third mode of using the main and side speakers 6-8. An instrumentalist can utilize the manner of the selectable use of the speakers according to preference.

Note that the when the effects are not used by turning off, the effects circuit 54 outputs a sound signal of a guitar sound in the same form as the input sound signal. It is possible according to the setting of the selector 55 to drive the side speakers 7 and 8 to emit sound of a sound signal before the internal effect processing, in addition to or instead of the main speaker 6.

In the above embodiment, the bass enhancing opening 11d is disposed under the apertures 11b and 11c. However, a position of forming the bass enhancing opening 11d can be modified in other suitable manners.

In the above embodiment, the bass enhancing ports 19 are initially separate and fitted on the front panel 11. However, the bass enhancing ports 19 can be formed together with the front panel 11. Also, the front panel 11 may be formed from resin. The bass enhancing ports 19 can be formed with the front panel 11 as a single piece.

In the embodiment, the electric guitar 30 is used with the guitar amplifier 2. However, a sound amplifier of the invention may be used with an electric bass or other musical instrument of an electric type, and also with an external sound signal source, such as a microphone. Audio sound may be human voice of speech, patterned sound of signals, ambient sound, or the like other than music, and may be derived from recorded audio sound or a data file of electronic data with sound generating code, to generate audio sound automatically.

In the present invention, it is possible to use any of various suitable techniques known in relation to the sound amplifier, including guitar amplifiers and the like, and high output instrument amplifiers for concerts and the like, loudspeakers of various types, including a speaker assembly of a multi unit type, disk players of various types, with various methods of inserting a disk for loading, and methods of containing and retaining the disk, various devices for aid of training of an instrument, and a combined use of an effects unit added between the electric guitar and the guitar amplifier.

Although the present invention has been fully described by way of the preferred embodiments thereof with reference to the accompanying drawings, various changes and modifications will be apparent to those having skill in this field. Therefore, unless otherwise these changes and modifications depart from the scope of the present invention, they should be construed as included therein.

What is claimed is:

1. A sound amplifier comprising:
an amplifier circuit for amplifying a sound signal input from an external sound signal source;
at least one main speaker for emitting sound according to said sound signal being amplified;
a player for playing back an audio signal recorded in a recording medium;
at least one playback speaker for emitting audio sound according to said audio signal being played back; and
a speaker box for containing said main speaker and said playback speaker in one space, said speaker box having a front panel in which plural apertures are formed and associated with said main speaker and said playback speaker.

2. A sound amplifier as defined in claim 1, wherein said speaker box includes a rear panel for closing a space behind said main speaker and said playback speaker.

3. A sound amplifier as defined in claim 2, wherein said main speaker is disposed in a middle of said front panel, and said playback speaker is disposed on each of right and left sides in said front panel.

4. A sound amplifier as defined in claim 2, further comprising a bass enhancing opening, formed in said front panel, for enhancing an output level of a low frequency component emitted by said playback speaker.

5. A sound amplifier as defined in claim 4, further comprising a cylindrical bass enhancing port, formed in said speaker box to extend from said bass enhancing opening, for enhancing an output level of a low frequency component emitted by said playback speaker.

6. A sound amplifier as defined in claim 2, further comprising an effects circuit, connected with said amplifier circuit, for effect processing of said sound signal.

7. A sound amplifier as defined in claim 6, further comprising an output mode selector for designating at least one of said main speaker and said playback speaker, and driving said at least one designated speaker with said sound signal after effect processing by said effects circuit.

8. A sound amplifier as defined in claim 2, further comprising a playback amplifier circuit for amplifying said audio signal to drive said playback speaker with said audio signal.

9. A sound amplifier as defined in claim 2, further comprising a player case, secured to an upper face of said speaker box, for containing said player.

10. A sound amplifier as defined in claim 2, further comprising a power source unit, contained in said speaker box, for supplying power for use in sound emission.

11. A sound amplifier as defined in claim 2, further comprising a grip portion secured to at least one side face of said speaker box.

12. A sound amplifier as defined in claim 1, wherein said sound signal source is an electric guitar, and said audio sound is adapted to guiding manual operation with said electric guitar.
